(19) United States
(12) Patent Application Publication
(10) Pub. No.: US 2025/0318244 A1
(43) Pub. Date: Oct. 9, 2025

(54) SEMICONDUCTOR MEMORY DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hiroaki KATOU, Nonoichi Ishikawa (JP); Tsuyoshi KACHI, Kanazawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/883,481

(22) Filed: Sep. 12, 2024

(30) Foreign Application Priority Data
Apr. 8, 2024 (JP) 2024-062367

(51) Int. Cl. H01L 29/423; H01L 29/06

(52) U.S. Cl. CPC H10D 64/519; H10D 62/124; H10D 64/518

(57) ABSTRACT

A semiconductor device includes a first electrode, a first semiconductor layer located on the first electrode, a second semiconductor layer located on the first semiconductor layer, a third semiconductor layer located on the second semiconductor layer, a second electrode facing the second semiconductor layer via an insulating layer, a plurality of contacts, and a third electrode connected to the plurality of contacts. The first semiconductor layer and the third semiconductor layer are of a first conductivity type. The second semiconductor layer is of a second conductivity type. The second semiconductor layer includes a first part and second parts. Distances between the first electrode and the second parts are less than a distance between the first electrode and the first part. The contacts are located respectively in regions directly above the second parts. The contacts are connected to the second and third semiconductor layers.

### CROSS-REFERENCE TO RELATED APPLICATIONS

This application is based upon and claims the benefit of priority from Japanese Patent Application No. 2024-062367, filed on Apr. 8, 2024; the entire contents of which are incorporated herein by reference.

### FIELD

Embodiments described herein relate generally to a semiconductor device.

### BACKGROUND

In recent years, vertical MOSFETS (Metal-Oxide-Semiconductor Field-Effect Transistors) have been used as semiconductor devices for power control. In such a semiconductor device, it is desirable to reduce the source-drain electrical resistance in the on-state while suppressing the source-drain leakage current in the off-state.

### BRIEF DESCRIPTION OF THE DRAWINGS

FIG. 1 is a plan view showing a semiconductor device according to a first embodiment;

FIG. 2 is a cross-sectional view along line A-A′ shown in FIG. 1;

FIG. 3 is a cross-sectional view along line B-B′ shown in FIG. 1;

FIG. 4 is a plan view showing a semiconductor device according to a second embodiment;

FIG. 5 is a cross-sectional view along line C-C′ shown in FIG. 4;

FIG. 6 is a plan view showing a semiconductor device according to a third embodiment;

FIG. 7 is a cross-sectional view along line D-D′ shown in FIG. 6;

FIG. 8 is a cross-sectional view along line E-E′ shown in FIG. 6;

FIG. 9 is a plan view showing a semiconductor device according to a fourth embodiment;

FIG. 10 is a cross-sectional view along line F-F′ shown in FIG. 9;

FIG. 11 is a cross-sectional view along line G-G′ shown in FIG. 9;

FIG. 12 is a plan view showing a semiconductor device according to a fifth embodiment;

FIG. 13 is a cross-sectional view along line H-H′ shown in FIG. 12;

FIG. 14A is a plan view showing a semiconductor device according to a sixth embodiment; and FIG. 14B is a partially enlarged plan view showing region I of FIG. 14A;

FIG. 15 is a cross-sectional view along line J-J′ shown in FIG. 14A;

FIG. 16 is a cross-sectional view along line K-K′ shown in FIG. 14A;

FIG. 17A is a plan view showing a semiconductor device according to a seventh embodiment; and FIG. 17B is a partially enlarged plan view showing region L of FIG. 17A;

FIG. 18 is a cross-sectional view along line M-M′ shown in FIG. 17A;

FIG. 19A is a plan view showing a semiconductor device according to an eighth embodiment; and FIG. 19B is a partially enlarged plan view showing region N of FIG. 19A;

FIG. 20 is a cross-sectional view along line O-O′ shown in FIG. 19A;

FIG. 21A is a plan view showing a semiconductor device according to a ninth embodiment; and FIG. 21B is a partially enlarged plan view showing region P of FIG. 21A;

FIG. 22 is a cross-sectional view along line Q-Q′ shown in FIG. 21A; and

FIG. 23A is a plan view showing a semiconductor device according to a tenth embodiment; and FIG. 23B is a partially enlarged plan view showing region R of FIG. 23A.

### DETAILED DESCRIPTION

In general, according to one embodiment, a semiconductor device includes a first electrode, a first semiconductor layer located on the first electrode, a second semiconductor layer located on the first semiconductor layer, a third semiconductor layer located on the second semiconductor layer, a second electrode facing the second semiconductor layer via an insulating layer, a plurality of contacts, and a third electrode connected to the plurality of contacts. The first semiconductor layer is of a first conductivity type. The second semiconductor layer is of a second conductivity type. The second semiconductor layer includes a first part and a plurality of second parts. Distances between the first electrode and the plurality of second parts are less than a distance between the first electrode and the first part. The third semiconductor layer is of the first conductivity type. The plurality of contacts are located respectively in regions directly above the plurality of second parts. The plurality of contacts are connected to the second and third semiconductor layers.

### First Embodiment

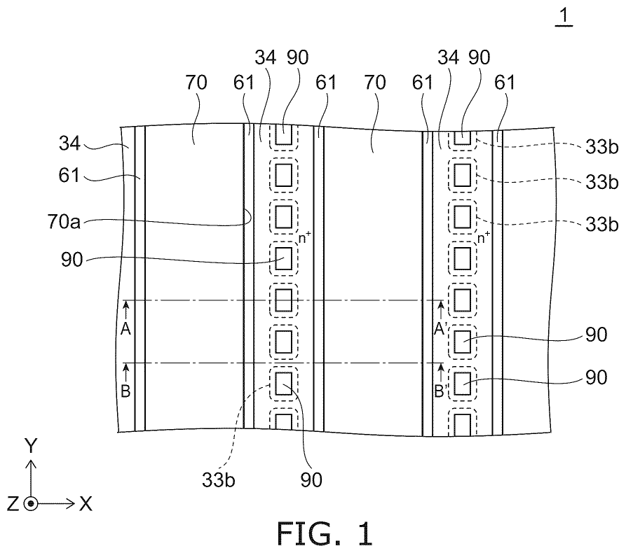

FIG. 1 is a plan view showing a semiconductor device according to the embodiment.

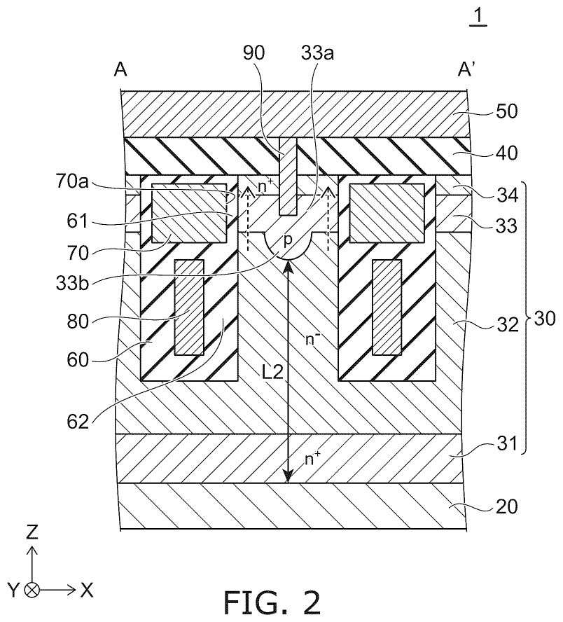

FIG. 2 is a cross-sectional view along line A-A′ shown in FIG. 1.

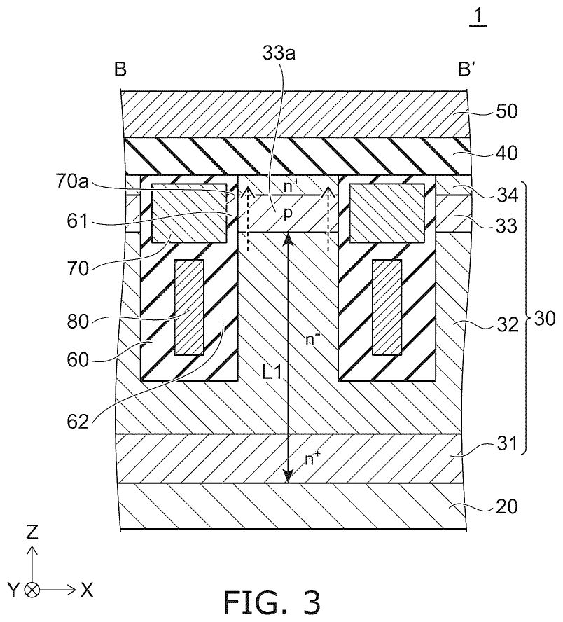

FIG. 3 is a cross-sectional view along line B-B′ shown in FIG. 1.

The drawings are schematic or conceptual, and are enhanced or simplified as appropriate. For example, the dimensional ratios of the components are adjusted with priority given to clarity of the technical idea over an accurate depiction of the actual product. The dimensional ratios and/or positional relationships of the components do not always match exactly between the drawings. This is similar for the other drawings described below as well.

As shown in FIGS. 1 to 3, a semiconductor device 1 according to the embodiment includes a drain electrode 20 (a first electrode), a semiconductor part 30, an insulating film 40, a source electrode 50 (a third electrode), an insulating member 60, a gate electrode 70 (a second electrode), a field plate electrode 80 (hereinbelow, a “FP electrode 80”; a fourth electrode), and a contact 90.

The drain electrode 20, the semiconductor part 30, the insulating film 40, and the source electrode 50 are arranged in this order. The insulating member 60 is located inside the upper portion of the semiconductor part 30 and contacts the insulating film 40. The gate electrode 70 and the FP electrode 80 are located inside the insulating member 60. The FP electrode 80 is located below the gate electrode 70 inside the insulating member 60. In other words, the FP electrode 80 is located between the drain electrode 20 and the gate electrode 70. The insulating film 40 and the source electrode 50 are not illustrated in FIG. 1. This is similar for the other plan views below as well.

The drain electrode 20, the source electrode 50, and the contact 90 are formed of conductive materials such as, for example, metals. The gate electrode 70 and the FP electrode 80 also are formed of conductive materials such as, for example, metals or polysilicon including an impurity. The insulating film 40 and the insulating member 60 are formed of insulating material such as, for example, silicon oxide.

The semiconductor part 30 is formed of a semiconductor material, and is formed of, for example, single-crystal silicon (Si) including an impurity. The semiconductor part 30 includes a drain layer 31 of an n⁺-conductivity type, a drift layer 32 of an n⁻-conductivity type, a base layer 33 (a second semiconductor layer) of a p-conductivity type, and a source layer 34 (a third semiconductor layer) of an n⁺-conductivity type. The first semiconductor layer includes the drain layer 31 and the drift layer 32. The drain layer 31, the drift layer 32, the base layer 33, and the source layer 34 are arranged in this order along the direction from the drain electrode 20 toward the source electrode 50.

The “n⁺-type” refers to a higher carrier concentration than the “n-type”; and the “n⁻-type” refers to a lower carrier concentration than the “n-type”. This is similar for the p-type as well. The “carrier concentration” means the effective impurity concentration contributing to the conduction of a semiconductor, and refers to the concentration excluding the cancelled portion when both an impurity that forms acceptors and an impurity that forms donors are included in a region.

Multiple insulating members 60 are included and extend in one direction in the upper portion of the semiconductor part 30. The gate electrode 70 is located inside the insulating member 60 and faces the base layer 33 via a gate insulating layer 61 which is a portion of the insulating member 60. The gate electrode 70 is connected to a gate pad (not illustrated) located on the semiconductor part 30. The FP electrode 80 faces the drift layer 32 via one part 62 of the insulating member 60. The FP electrode 80 is connected to the source electrode 50. In the specification, “connected” means an electrical connection.

In the specification, an XYZ orthogonal coordinate system is employed for convenience of description. The direction from the drain electrode 20 toward the source electrode 50 is taken as a “Z-direction”; the direction in which the multiple insulating members 60 are arranged is taken as an “X-direction”; and the direction in which each insulating member 60 extends is taken as a “Y-direction”. Although the Z-direction also is called “up/above/higher than”, and the opposite direction also is called “down/below/lower than”, these expressions are for convenience and are independent of the direction of gravity.

Multiple contacts 90 are included. Each contact 90 has a substantially columnar shape of which the axial direction extends in the Z-direction. The upper end of the contact 90 contacts the lower surface of the source electrode 50. The upper portion of the contact 90 is located inside the insulating film 40. The lower portion of the contact 90 is located inside the source layer 34 and inside the base layer 33 and contacts the source layer 34 and the base layer 33. As a result, the contact 90 connects the base layer 33 and the source layer 34 to the source electrode 50. The contact 90 may be formed to be a continuous body with the source electrode 50.

The multiple contacts 90 are arranged along a side surface 70a of the gate electrode 70 facing the base layer 33. According to the embodiment, the multiple contacts 90 are arranged in one column along the Y-direction at parts of the semiconductor part 30 located between the insulating members 60. The contact 90 is separated from the insulating member 60. For example, the contact 90 is located at the X-direction central portion of the part of the semiconductor part 30 located between the insulating members 60.

The base layer 33 includes a first part 33a and multiple second parts 33b. The second parts 33b are located in regions directly under the contacts 90; and the lower surfaces of the second parts 33b protrude lower than the lower surface of the first part 33a. Therefore, a distance L2 between the drain electrode 20 and the second part 33b is less than a distance L1 between the drain electrode 20 and the first part 33a. In other words, L2<L1.

In the manufacturing processes of the semiconductor device 1, the second part 33b is formed by forming a hole in the semiconductor part 30 for forming the contact 90, and then ion-implanting an impurity that forms acceptors via the hole. Subsequently, the contact 90 is formed by filling a conductive material into the hole. Therefore, the second part 33b has, for example, a downwardly convex substantially hemispherical shape centered on the lower end of the contact 90. The center of the second part 33b is positioned on an extension line of the central axis of the contact 90. The multiple second parts 33b are arranged to be separated from each other along the Y-direction.

The base layer 33 may include platinum (Pt). The drift layer 32 also may include platinum. Platinum also may be ion-implanted into the semiconductor part 30 via the hole for forming the contact 90 in the manufacturing processes of the semiconductor device 1. Therefore, the platinum concentration of the base layer 33 has a maximum value at the lower end vicinity of the contact 90.

Operations of the semiconductor device 1 will now be described.

When a voltage is applied to cause the drain electrode 20 to be positive and the source electrode 50 to be negative, a depletion layer spreads with the interface between the n⁻-type drift layer 32 and the p-type base layer 33 as a starting point. When a potential that is greater than a threshold is applied to the gate electrode 70 in this state, an inversion layer is formed in the part of the base layer 33 facing the gate electrode 70, i.e., the part of the base layer 33 contacting the gate insulating layer 61; and a current flows from the drain electrode 20 toward the source electrode 50. As a result, the semiconductor device 1 is set to an on-state. On the other hand, when the potential of the gate electrode 70 is set to be less than the threshold, the inversion layer disappears; and a current does not flow. As a result, the semiconductor device 1 is switched to an off-state. When the semiconductor device 1 is switched to the off-state, the voltage between the drain electrode 20 and the source electrode 50 is applied to the depletion layer.

In the semiconductor device 1, the base layer 33 includes the second part 33b directly under the contact 90. As a result, the depletion layer can be distant to the contact 90; and the leakage current (hereinbelow, also called the “off-current”) flowing between the drain electrode 20 and the source electrode 50 in the off-state can be reduced.

The contacts 90 are arranged to be separated from each other along the Y-direction; and the second parts 33b of the base layer 33 also are arranged to be separated from each other along the Y-direction. Therefore, the second parts 33b are not located at the regions directly under the parts between the contacts 90 in the Y-direction. As a result, the electrical resistance (hereinbelow, also called the “on-resistance”) between the drain electrode 20 and the source electrode 50 in the on-state does not easily increase.

For example, even if the X-direction positions of the contact 90 and the second part 33b are shifted from the design positions due to the error when manufacturing and the second part 33b contacts the insulating member 60, the second part 33b does not easily contact the insulating member 60 at the cross section shown in FIG. 3 that does not include the contact 90; and the channel length does not easily increase. Therefore, the on-resistance does not easily increase.

Effects of the embodiment will now be described.

According to the embodiment, by locating the multiple contacts 90 to be separated from each other, and by locating the second parts 33b of the base layer 33 in the regions directly under the contacts 90, the depletion layer can be distant to the contacts 90 in the off-state; and a region of the base layer 33 at which the second parts 33b are not located can be ensured at the part contacting the insulating member 60. As a result, the semiconductor device 1 that can reduce both the off-current and the on-resistance can be realized.

According to the embodiment, the base layer 33 includes platinum. As a result, a level due to the platinum is formed in the silicon bandgap of the base layer 33. As a result, when a forward voltage is applied to the p-n interface between the n⁻-type drift layer 32 and the p-type base layer 33 and then a reverse voltage is applied to the p-n interface, the electrons and the holes that penetrated the interior of the semiconductor part 30 recombine via the level due to the platinum. As a result, the electrons and the holes inside the semiconductor part 30 quickly disappear; and the Qrr (the reverse recovery charge) is reduced.

The platinum concentration distribution in the semiconductor part 30 has a maximum value at the lower end vicinity of the contact 90. According to the embodiment, because the base layer 33 includes the second part 33b, the part that has a high platinum concentration is distant to the depletion layer when the semiconductor device 1 is in the off-state. As a result, the electric field that is applied to the part having the high platinum concentration can be reduced, and the leakage current can be reduced.

### Second Embodiment

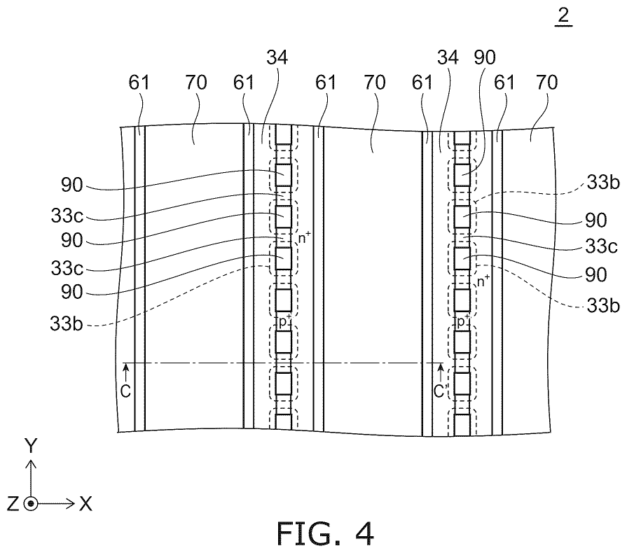

FIG. 4 is a plan view showing a semiconductor device according to the embodiment.

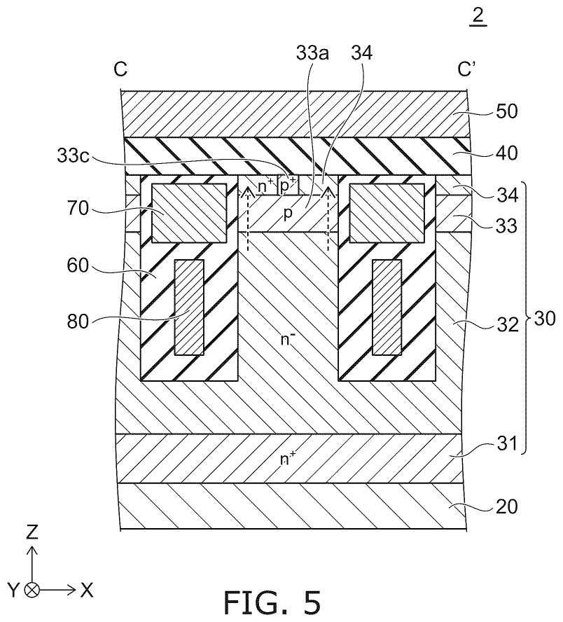

FIG. 5 is a cross-sectional view along line C-C′ shown in FIG. 4.

As shown in FIGS. 4 and 5, compared with the semiconductor device 1 according to the first embodiment, the semiconductor device 2 according to the embodiment includes multiple third parts 33c in addition to the first part 33a and the second parts 33b of the base layer 33.

The third part 33c is located on the first part 33a between the adjacent contacts 90. Therefore, the third part 33c contacts the source layer 34 in the X-direction, contacts the contact 90 in the Y-direction, and contacts the insulating film 40 and the first part 33a of the base layer 33 in the Z-direction. The conductivity type of the third part 33c is the p⁺-type. The carrier concentration of the third part 33c is greater than the carrier concentrations of the first part 33a and the second part 33b.

According to the embodiment, because the base layer 33 includes the third part 33c, the source potential that is conducted from the source electrode 50 via the contact 90 is easily conducted to the entire base layer 33 via the third part 33c of the base layer 33. As a result, compared with the first embodiment, the increase of the potential of the base layer 33 can be effectively suppressed, and the avalanche resistance can be improved. Otherwise, the configuration, operations, and effects according to the embodiment are similar to those of the first embodiment.

### Third Embodiment

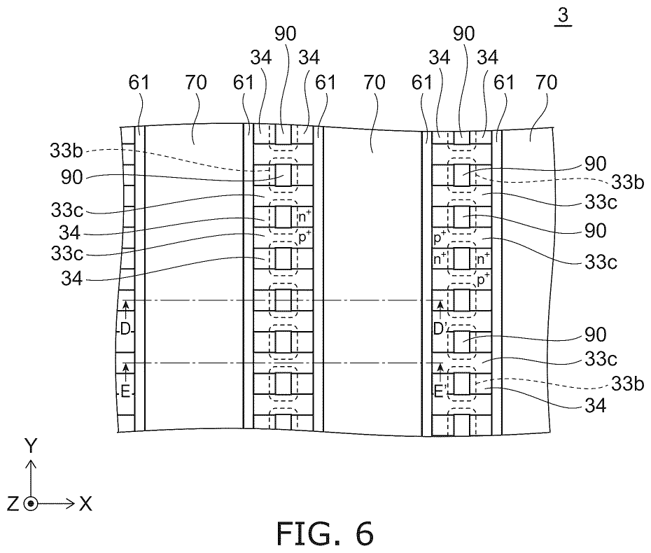

FIG. 6 is a plan view showing a semiconductor device according to the embodiment.

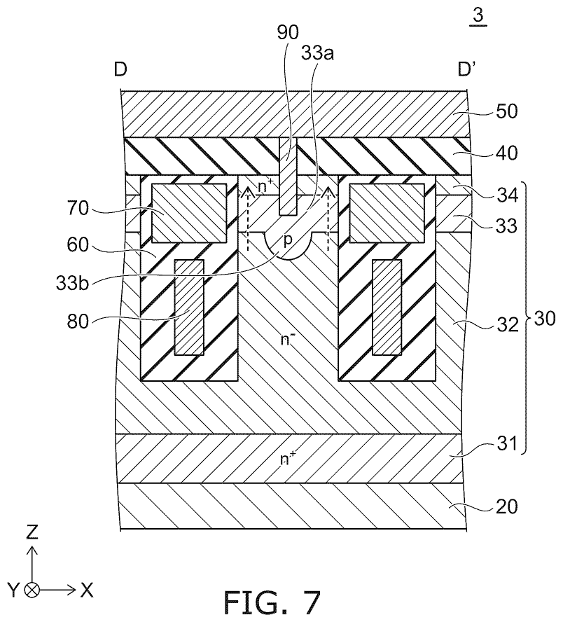

FIG. 7 is a cross-sectional view along line D-D′ shown in FIG. 6.

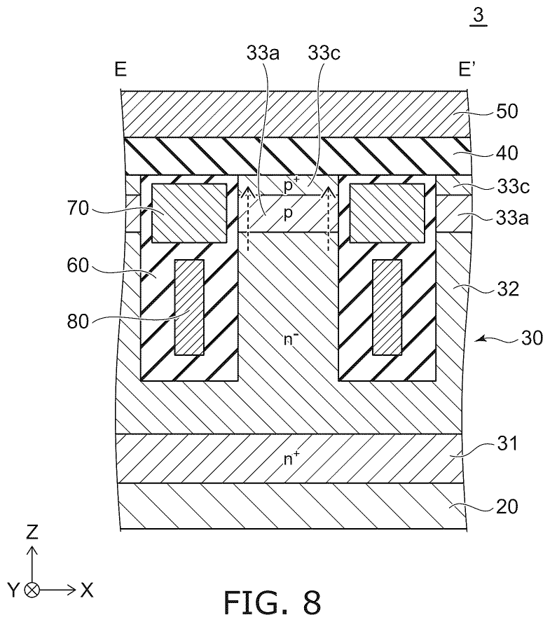

FIG. 8 is a cross-sectional view along line E-E′ shown in FIG. 6.

As shown in FIGS. 6 to 8, the semiconductor device 3 according to the embodiment differs from the semiconductor device 2 according to the second embodiment in that the third part 33c of the base layer 33 spreads over the entire width of the base layer 33 in the X-direction. For example, the third part 33c contacts the insulating member 60 at the two X-direction sides. In such a case, the source layer 34 is not interposed between the third part 33c and the insulating member 60.

Because the width of the third part 33c of the base layer 33 of the semiconductor device 3 according to the embodiment is greater than that of the semiconductor device 2 according to the second embodiment, the source potential can be more effectively conducted to the entire base layer 33; and the avalanche resistance can be improved even further. On the other hand, the contact area between the source layer 34 and the insulating member 60 of the semiconductor device 2 also is greater than that of the semiconductor device 3, and so the channel width is wide, and the on-resistance is low. Otherwise, the configuration, operations, and effects according to the embodiment are similar to those of the second embodiment.

### Fourth Embodiment

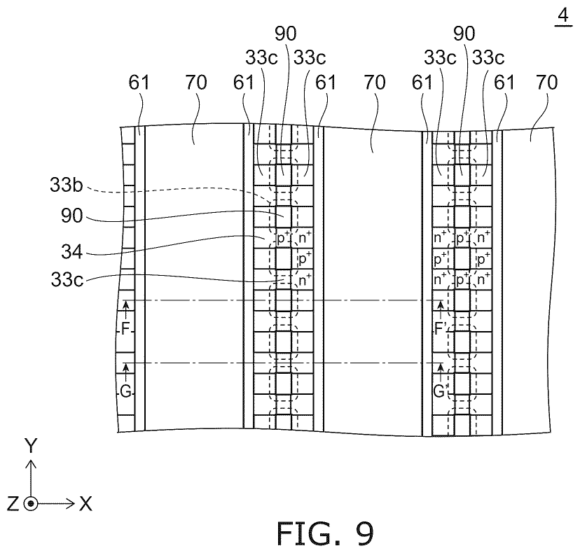

FIG. 9 is a plan view showing a semiconductor device according to the embodiment.

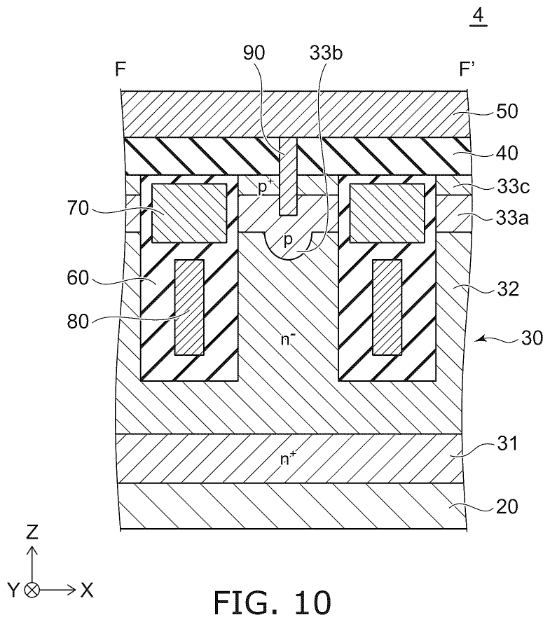

FIG. 10 is a cross-sectional view along line F-F′ shown in FIG. 9.

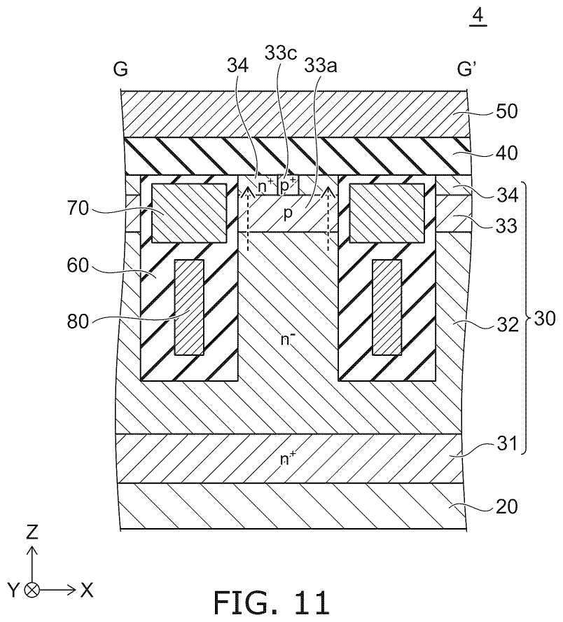

FIG. 11 is a cross-sectional view along line G-G′ shown in FIG. 9.

As shown in FIGS. 9 to 11, the semiconductor device 4 according to the embodiment differs from the semiconductor device 2 according to the second embodiment in that the third part 33c of the base layer 33 is located not only between the contacts 90 in the Y-direction, but also at the two X-direction sides of the contact 90.

In other words, the third part 33c is located at the two X-direction sides and the two Y-direction sides of the contact 90. The part of the third part 33c located at the two X-direction sides of the contact 90 contacts the contact 90 at one X-direction side, and contacts the insulating member 60 at the other X-direction side.

In the semiconductor device 4 according to the embodiment, compared with the semiconductor device 2 according to the second embodiment, the third part 33c of the base layer 33 is located at the two X-direction sides and the two Y-direction sides of the contact 90, and so the potential of the source electrode 50 can be more effectively conducted to the entire base layer 33. As a result, the avalanche resistance can be improved even further. On the other hand, the contact area between the source layer 34 and the insulating member 60 of the semiconductor device 2 is greater than that of the semiconductor device 4, and so the channel width is wide, and the on-resistance is low. Otherwise, the configuration, operations, and effects according to the embodiment are similar to those of the second embodiment.

### Fifth Embodiment

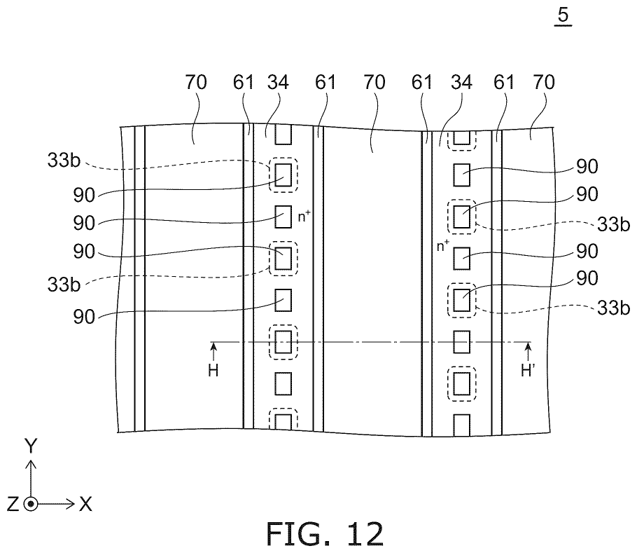

FIG. 12 is a plan view showing a semiconductor device according to the embodiment.

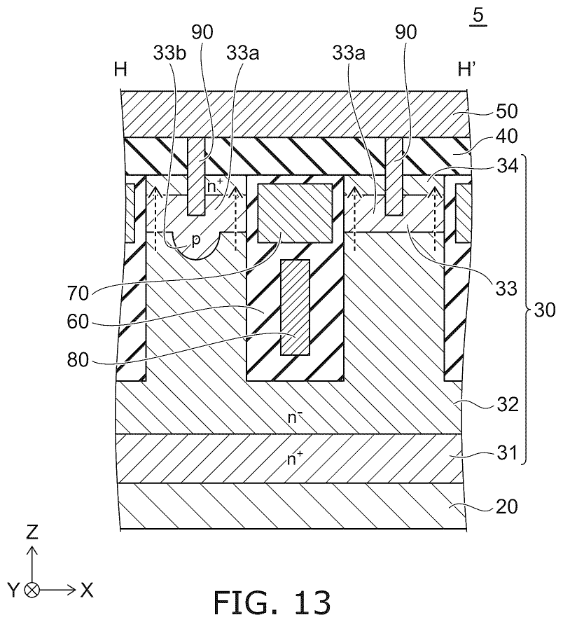

FIG. 13 is a cross-sectional view along line H-H′ shown in FIG. 12.

As shown in FIGS. 12 and 13, the semiconductor device 5 according to the embodiment differs from the semiconductor device 1 according to the first embodiment in that among the multiple contacts 90 arranged along the Y-direction, the second parts 33b of the base layer 33 are located in only regions directly under every other contact 90, and are not located in the regions directly under the other contacts 90. For the multiple contacts 90 arranged along the X-direction as well, the second parts 33b are located only in the regions directly under every other contact 90, and are not located in the regions directly under the other contacts 90. Therefore, when viewed along the Z-direction, the contacts 90 are arranged in a matrix configuration along the X-direction and the Y-direction, whereas the second parts 33b are arranged in a staggered configuration.

The number of the second parts 33b of the semiconductor device 5 according to the embodiment is less than that of the semiconductor device 1 according to the first embodiment. Therefore, an increase of the channel length caused by the second parts 33b can be suppressed. In other words, even when the X-direction positions of the contact 90 and the second part 33b are shifted from the center between the insulating members 60 due to errors of the manufacturing processes, etc., the second part 33b can be prevented from contacting the insulating member 60; and an increase of the Z-direction length of the region of the base layer 33 contacting the insulating member 60 can be suppressed. As a result, the on-resistance of the semiconductor device 5 is less than that of the semiconductor device 1. On the other hand, in the semiconductor device 1, compared with the semiconductor device 5, the depletion layer can be more reliably distant to the contact 90, and so the off-current is low. Otherwise, the configuration, operations, and effects according to the embodiment are similar to those of the first embodiment.

### Sixth Embodiment

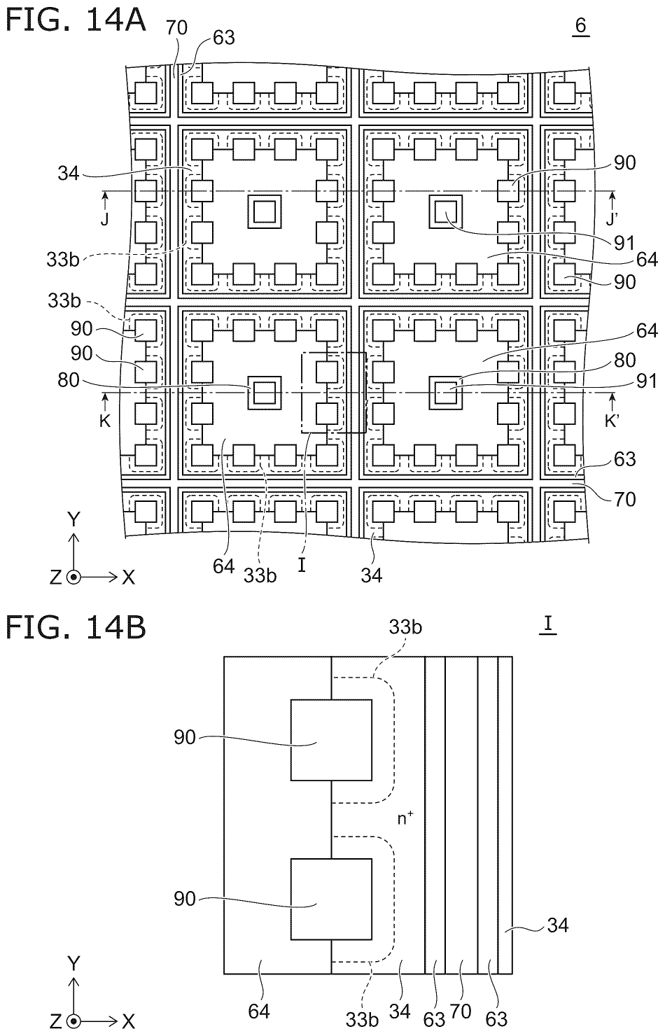

FIG. 14A is a plan view showing a semiconductor device according to the embodiment; and FIG. 14B is a partially enlarged plan view showing region I of FIG. 14A.

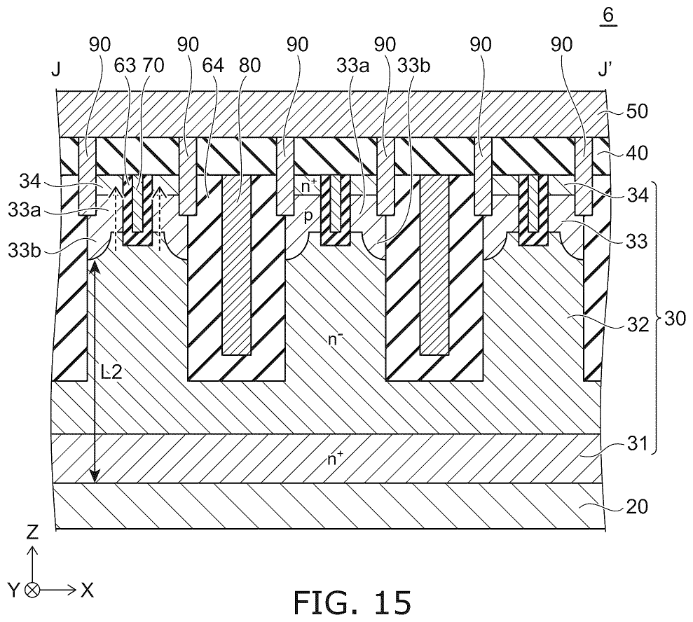

FIG. 15 is a cross-sectional view along line J-J′ shown in FIG. 14A.

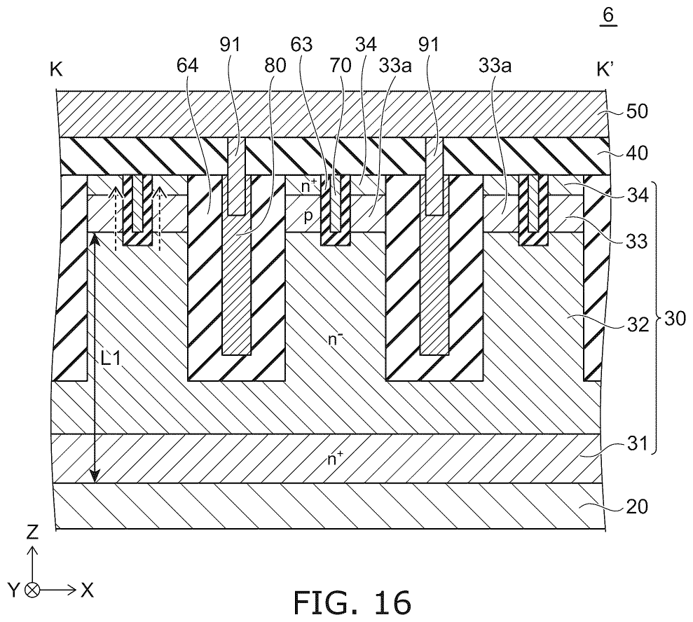

FIG. 16 is a cross-sectional view along line K-K′ shown in FIG. 14A.

As shown in FIGS. 14A to 16, the semiconductor device 6 according to the embodiment differs from the semiconductor device 1 according to the first embodiment in that the shapes and locations of the gate electrode 70 and the FP electrode 80 are different; a gate insulating layer 63 and an insulating member 64 are included instead of the insulating member 60; and a contact 91 is included.

When viewed along the Z-direction, the gate electrode 70 has a lattice shape. In other words, the gate electrode 70 includes multiple parts extending in the X-direction and multiple parts extending in the Y-direction. The gate insulating layer 63 is located between the gate electrode 70 and the semiconductor part 30. Accordingly, the gate insulating layer 63 also has a lattice shape when viewed along the Z-direction. The gate electrode 70 faces the semiconductor part 30 via the gate insulating layer 63.

The FP electrodes 80 are arranged in a dot configuration. Multiple FP electrodes 80 are included, and are arranged in a matrix configuration along the X-direction and the Y-direction. Each of the multiple FP electrodes 80 is surrounded with the lattice-shaped gate electrode 70 when viewed along the Z-direction. The FP electrode 80 has a columnar shape of which the axial direction extends in the Z-direction.

The insulating member 64 is located between the FP electrode 80 and the semiconductor part 30. In other words, the FP electrodes 80 are located respectively inside the insulating members 64 and face the semiconductor part 30 via the insulating members 64. The insulating members 64 are separated from the gate insulating layers 63 with the semiconductor part 30 interposed.

The multiple contacts 90 are arranged to be separated from each other at the boundary between the insulating member 64 and the semiconductor part 30. The multiple contacts 90 are arranged along the side surface 70a of the gate electrode 70 facing the base layer 33. Therefore, the multiple contacts 90 are arranged so that each FP electrode 80 is surrounded with the multiple contacts 90 when viewed along the Z-direction. A portion of each contact 90 is located inside the semiconductor part 30; and the remainder is located inside the insulating member 64.

Similarly to the first embodiment, the base layer 33 includes the first part 33a and the second part 33b. The second parts 33b are located in the regions of the semiconductor part 30 directly under the contacts 90. The second parts 33b protrude downward with respect to the first part 33a. Therefore, the distance L2 between the drain electrode 20 and the second part 33b is less than the distance L1 between the drain electrode 20 and the first part 33a. The multiple second parts 33b are separated from each other; and the drift layer 32 is interposed between the adjacent second parts 33b.

The contact 91 is located in the region directly above the FP electrode 80. The upper end of the contact 91 is connected to the source electrode 50; and the lower end of the contact 91 is connected to the FP electrode 80. As a result, the FP electrode 80 is connected to the source electrode 50 via the contact 91. The shape of the contact 91 may be the same as or different from the shape of the contact 90. The contact 90 and the contact 91 may be formed to be a continuous body with the source electrode 50.

Effects of the embodiment will now be described.

According to the embodiment as well, the second part 33b of the base layer 33 is located in the region directly under the contact 90, and so the depletion layer can be distant to the contact 90. As a result, the leakage current (the off-current) between the drain electrode 20 and the source electrode 50 in the off-state can be reduced.

The second parts 33b of the base layer 33 are discontinuously arranged along the gate electrode 70, and so the second parts 33b can be reliably separated from the gate insulating layer 63 at the parts of the base layer 33 at which the second parts 33b are not located. As a result, a part at which the channel length is not increased by the second parts 33b can be ensured, and a low on-resistance state can be maintained. Thus, a low off-current and a low on-resistance both can be realized.

By providing each contact 90 to straddle the insulating member 64 and the semiconductor part 30, the second part 33b is easily separated from the gate insulating layer 63. As a result, a channel length increase due to the second part 33b can be suppressed, and an increase of the on-resistance can be suppressed. Otherwise, the configuration, operations, and effects according to the embodiment are similar to those of the first embodiment.

### Seventh Embodiment

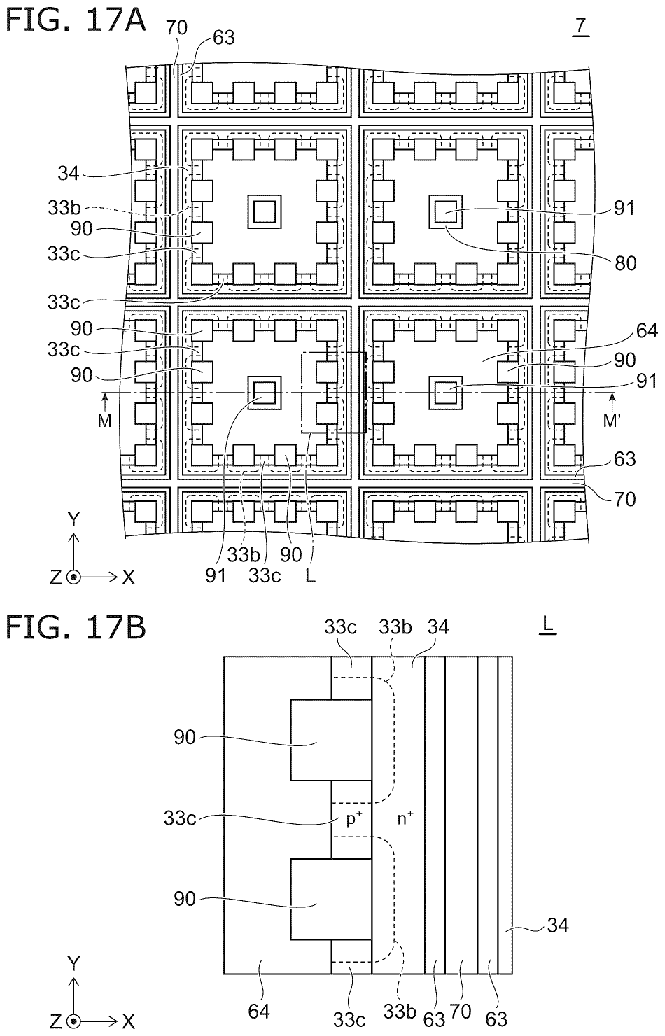

FIG. 17A is a plan view showing a semiconductor device according to the embodiment; and FIG. 17B is a partially enlarged plan view showing region L of FIG. 17A.

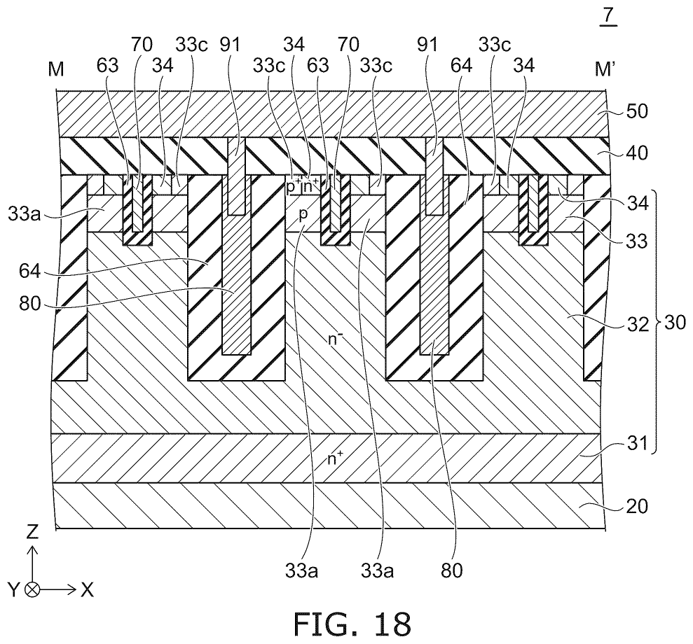

FIG. 18 is a cross-sectional view along line M-M′ shown in FIG. 17A.

As shown in FIGS. 17A and 18, the semiconductor device 7 according to the embodiment differs from the semiconductor device 6 according to the sixth embodiment in that the base layer 33 includes the multiple third parts 33c in addition to the first part 33a and the second parts 33b.

The third part 33c is located on the first part 33a between the adjacent contacts 90. Therefore, the third part 33c contacts the source layer 34 at the gate electrode 70 side, contacts the insulating member 64 at the FP electrode 80 side, contacts the contact 90 in two directions along the interface between the base layer 33 and the insulating member 64, and contacts the insulating film 40 and the first part 33a of the base layer 33 in the Z-direction. The carrier concentration of the third part 33c is greater than the carrier concentrations of the first part 33a and the second part 33b.

For example, the third part 33c of the base layer 33 can be formed by ion-implanting an impurity that forms acceptors by using, as a mask, an opening provided in a region including the boundary between the semiconductor part 30 and the insulating member 64. In such a case, the impurity that is implanted into the insulating member 64 does not contribute to the conduction; and the part of the third part 33c that has the highest carrier concentration can be located at the vicinity of the interface between the base layer 33 and the insulating member 64. As a result, the third part 33c can be prevented from being located at the vicinity of the gate insulating layer 63; and an increase of the on-resistance can be suppressed.

According to the embodiment, because the base layer 33 includes the third part 33c, the source potential that is conducted from the source electrode 50 via the contact 90 is easily conducted to the entire base layer 33. As a result, compared with the sixth embodiment, the increase of the potential of the base layer 33 can be effectively suppressed, and the avalanche resistance can be improved. Otherwise, the configuration, operations, and effects according to the embodiment are similar to those of the sixth embodiment.

### Eighth Embodiment

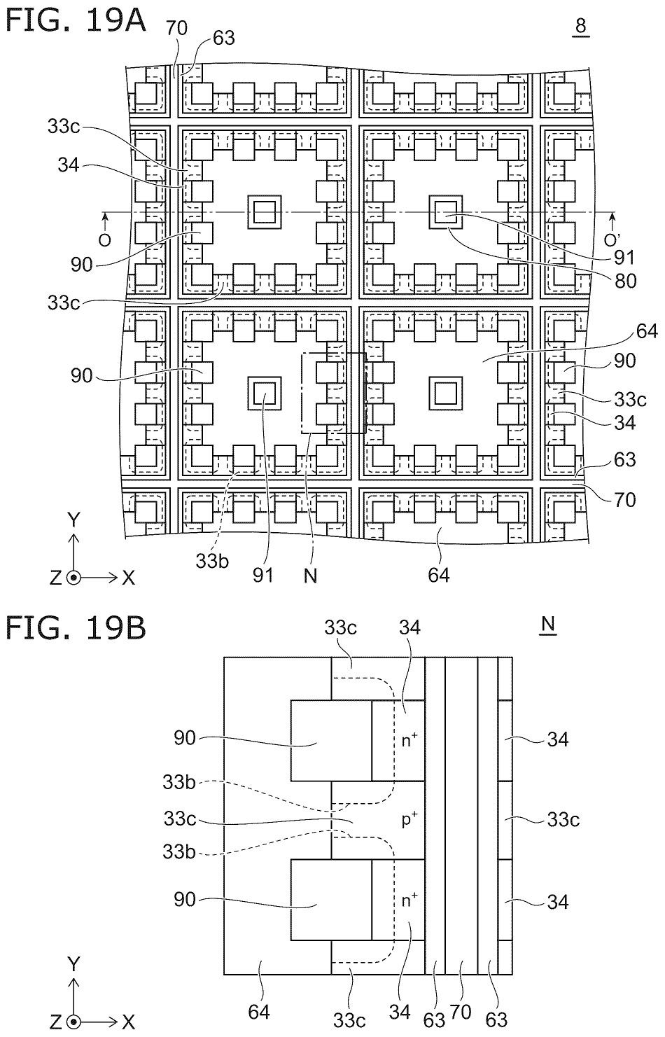

FIG. 19A is a plan view showing a semiconductor device according to the embodiment; and FIG. 19B is a partially enlarged plan view showing region N of FIG. 19A.

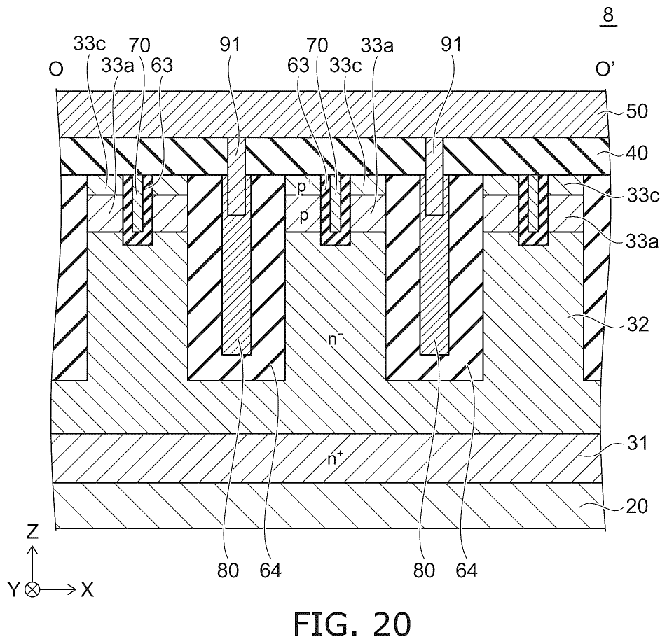

FIG. 20 is a cross-sectional view along line O-O′ shown in FIG. 19A.

As shown in FIGS. 19A and 20, the semiconductor device 8 according to the embodiment differs from the semiconductor device 7 according to the seventh embodiment in that the third part 33c of the base layer 33 spreads over the entire width of the base layer 33 in the direction from the insulating member 64 toward the gate insulating layer 63. For example, the third part 33c contacts both the insulating member 64 and the gate insulating layer 63. In such a case, the source layer 34 is not interposed between the third part 33c and the gate insulating layer 63.

In the semiconductor device 8 according to the embodiment, compared with the semiconductor device 7 according to the seventh embodiment, the area of the third part 33c of the base layer 33 is large, and so the avalanche resistance can be improved even further. On the other hand, the contact area between the source layer 34 and the gate insulating layer 63 is larger for the semiconductor device 7 than for the semiconductor device 8, and so the channel width is wider, and the on-resistance is lower. Otherwise, the configuration, operations, and effects according to the embodiment are similar to those of the seventh embodiment.

### Ninth Embodiment

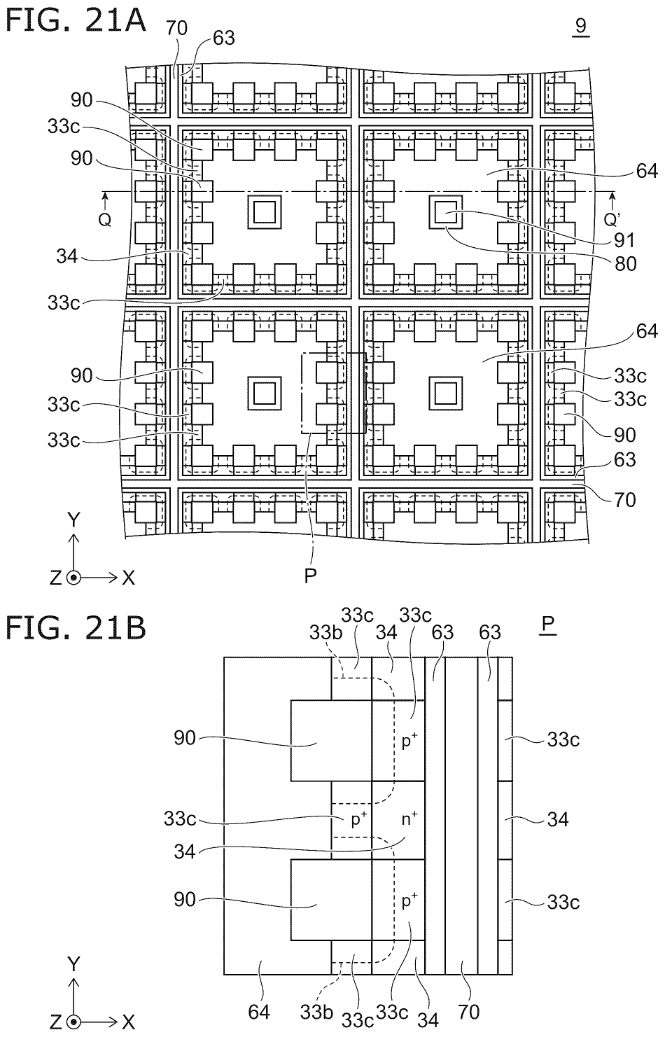

FIG. 21A is a plan view showing a semiconductor device according to the embodiment; and FIG. 21B is a partially enlarged plan view showing region P of FIG. 21A.

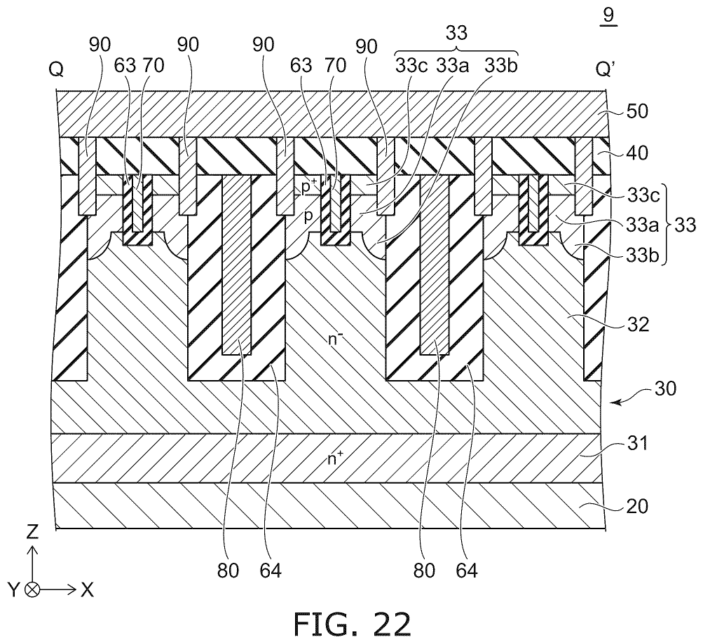

FIG. 22 is a cross-sectional view along line Q-Q′ shown in FIG. 21A.

As shown in FIGS. 21A and 22, the semiconductor device 9 according to the embodiment differs from the semiconductor device 7 according to the seventh embodiment in that the third part 33c of the base layer 33 also is located between the contact 90 and the gate insulating layer 63. For example, the third part 33c that is located between the contact 90 and the gate insulating layer 63 contacts both the contact 90 and the gate insulating layer 63.

In the semiconductor device 9 according to the embodiment, compared with the semiconductor device 7 according to the seventh embodiment, the area of the third part 33c of the base layer 33 is larger, and so the avalanche resistance can be improved even further. On the other hand, the contact area between the source layer 34 and the gate insulating layer 63 of the semiconductor device 7 is greater than that of the semiconductor device 9, and so the channel width is wider, and the on-resistance is lower. Otherwise, the configuration, operations, and effects according to the embodiment are similar to those of the seventh embodiment.

### Tenth Embodiment

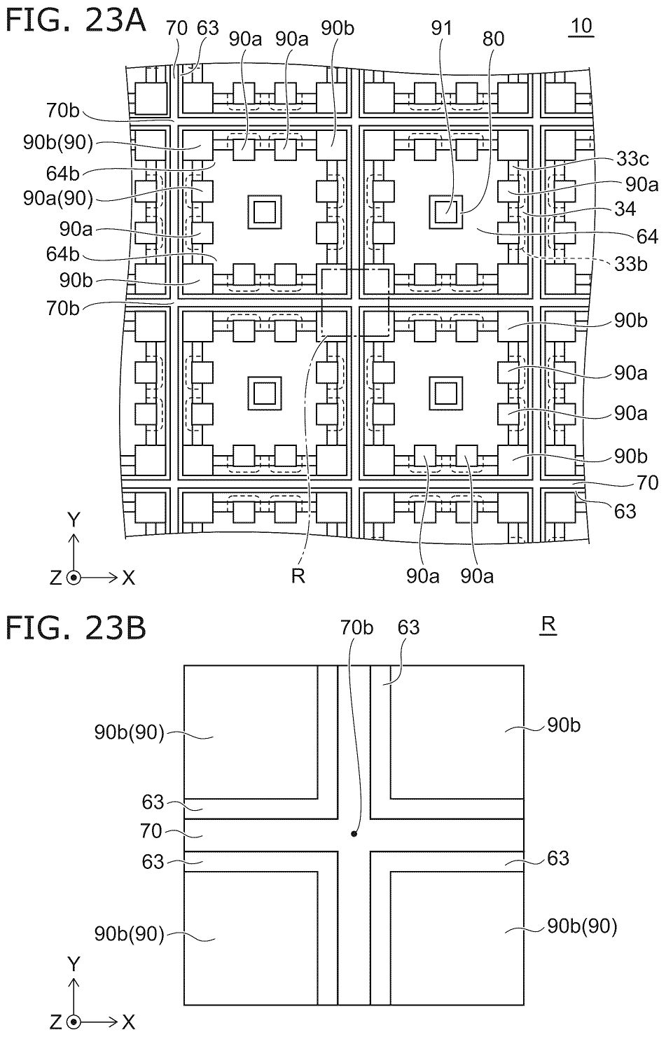

FIG. 23A is a plan view showing a semiconductor device according to the embodiment; and FIG. 23B is a partially enlarged plan view showing region R of FIG. 23A.

As shown in FIG. 23A, the semiconductor device 10 according to the embodiment differs from the semiconductor device 7 according to the seventh embodiment in that diameters of some of the contacts 90 are different. In other words, when viewed along the Z-direction, the multiple contacts 90 include a contact 90b located between an intersection part 70b of the lattice-shaped gate electrode 70 and a corner part 64b of the insulating member 64, and other contacts 90a.

The diameter of the contact 90b is greater than the diameter of the contact 90a. The diameter of the contact 90 refers to the maximum diameter when viewed along the Z-direction. For example, when the contact 90 is rectangular when viewed along the Z-direction, the diameter of the contact 90 is the length of the diagonal of the rectangle. The distance between the contact 90b and the intersection part 70b of the gate electrode 70 is less than the distance between the intersection part 70b and the contact 90a. The contact 90b may contact the gate insulating layer 63, may be separated from the gate insulating layer 63 with the source layer 34 interposed, or may be separated from the gate insulating layer 63 with the third part 33c of the base layer 33 interposed.

In the semiconductor device 10 according to the embodiment, compared with the semiconductor device 7 according to the seventh embodiment, concentration of the electric field at the bottom portion of the intersection part 70b of the gate electrode 70 can be relaxed. Also, by reducing the volume of the base layer 33 at the vicinity of the intersection part 70b of the gate electrode 70, depletion in the off-state can be promoted, and the leakage current (the off-current) can be reduced even further. On the other hand, the contact area between the source layer 34 and the gate insulating layer 63 of the semiconductor device 7 is greater than that of the semiconductor device 10, and so the channel width is wider, and the on-resistance is lower. Otherwise, the configuration, operations, and effects according to the embodiment are similar to those of the seventh embodiment.

Although examples are described in the embodiments above in which the FP electrode 80 is rectangular when viewed along the Z-direction, the invention is not limited thereto. The shape of the FP electrode 80 when viewed along the Z-direction may be, for example, circular, polygonal such as oval, hexagonal, etc.

Although examples are described in the sixth to tenth embodiments above in which the FP electrodes 80 are arranged in a matrix configuration along the X-direction and the Y-direction, the invention is not limited thereto. For example, the FP electrodes 80 may be located at positions corresponding to vertices of equilateral triangles when viewed along the Z-direction.

According to the embodiments above, a semiconductor device can be realized in which both a reduced leakage current in the off-state and a reduced resistance in the on-state can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Additionally, the embodiments described above can be combined mutually.

Embodiments include the following aspects.

Note 1 A semiconductor device, comprising:
a first electrode;
a first semiconductor layer located on the first electrode, the first semiconductor layer being of a first conductivity type;
a second semiconductor layer located on the first semiconductor layer, the second semiconductor layer being of a second conductivity type, the second semiconductor layer including a first part and a plurality of second parts, distances between the first electrode and the plurality of second parts being less than a distance between the first electrode and the first part;
a third semiconductor layer located on the second semiconductor layer, the third semiconductor layer being of the first conductivity type;
a second electrode facing the second semiconductor layer via an insulating layer;
a plurality of contacts located respectively in regions directly above the plurality of second parts, the plurality of contacts being connected to the second and third semiconductor layers; and
a third electrode connected to the plurality of contacts.

Note 2

The device according to note 1, wherein
the plurality of contacts is arranged along a side surface of the second electrode facing the second semiconductor layer.

Note 3

The device according to note 1 or 2, wherein
the second semiconductor layer includes silicon and platinum.

Note

The device according to any one of notes 1-3, wherein a plurality of the second electrodes is included,
the plurality of second electrodes is arranged along a first direction,
each of the plurality of second electrodes extends in a second direction crossing the first direction, and
the contacts are separated from the insulating layer.

Note 5

The device according to note 4, wherein
the second parts are separated from the insulating layer.

Note 6

The device according to note 4 or 5, wherein
the second semiconductor layer further includes a third part located between adjacent contacts among the plurality of contacts,
the third part contacts the adjacent contacts, and
the third part has a higher carrier concentration than the first part.

Note 7

The device according to note 6, wherein
a portion of the third semiconductor layer is located between the second electrode and the third part.

Note 8

The device according to note 6, wherein
the third part contacts the insulating layer.

Note 9

The device according to note 6, wherein
the third part also is located between the insulating layer and the contact.

Note 10

The device according to any one of notes 4-9, wherein
the second parts are located in regions directly under every other contact in the second direction among the plurality of contacts, and are not located in regions directly under contacts other than every other contact among the plurality of contacts.

Note 11

The device according to any one of notes 4-10, further comprising:
a fourth electrode located between the first electrode and the second electrode,
the fourth electrode being connected to the third electrode,
the fourth electrode facing the first semiconductor layer via an insulating member.

Note 12

The device according to any one of notes 1-3, further comprising:
a plurality of fourth electrodes arranged in a matrix configuration along a first direction and a second direction crossing the first direction,
the plurality of fourth electrodes being connected to the third electrode,
the plurality of fourth electrodes facing the second semiconductor layer via an insulating member,
the second electrode including
   a part extending in the first direction, and
   a part extending in the second direction.

Note 13

The device according to note 12, wherein
the second electrode has a lattice shape surrounding the fourth electrodes when viewed along a third direction orthogonal to the first and second directions.

Note 14

The device according to note 12 or 13, wherein
the second parts contact the insulating layer.

Note 15

The device according to any one of notes 12-14, wherein
the second semiconductor layer further includes a third part located between adjacent contacts among the plurality of contacts,
the third part contacts the adjacent contacts, and
the third part has a higher carrier concentration than the second part.

Note 1

The device according to note 15, wherein
a portion of the third semiconductor layer is located between the second electrode and the third part.

Note 17

The device according to note 15, wherein
the third part contacts the insulating layer.

Note 18

The device according to note 15, wherein
the third part also is located between the insulating layer and the contact.

Note 19

The device according to any one of notes 12-18, wherein
the plurality of contacts includes a first contact and a second contact,
a diameter of the second contact is greater than a diameter of the first contact, and
a distance between the second contact and an intersection part of the second electrode is less than the distance between the first contact and the intersection part.

What is claimed is:

1. A semiconductor device, comprising:
a first electrode;
a first semiconductor layer located on the first electrode, the first semiconductor layer being of a first conductivity type;
a second semiconductor layer located on the first semiconductor layer, the second semiconductor layer being of a second conductivity type, the second semiconductor layer including a first part and a plurality of second parts, distances between the first electrode and the plurality of second parts being less than a distance between the first electrode and the first part;
a third semiconductor layer located on the second semiconductor layer, the third semiconductor layer being of the first conductivity type;
a second electrode facing the second semiconductor layer via an insulating layer;
a plurality of contacts located respectively in regions directly above the plurality of second parts, the plurality of contacts being connected to the second and third semiconductor layers; and
a third electrode connected to the plurality of contacts.

2. The device according to claim 1, wherein
the plurality of contacts is arranged along a side surface of the second electrode facing the second semiconductor layer.

3. The device according to claim 1, wherein
the second semiconductor layer includes silicon and platinum.

4. The device according to claim 1, wherein
a plurality of the second electrodes is included,
the plurality of second electrodes is arranged along a first direction,
each of the plurality of second electrodes extends in a second direction crossing the first direction, and
the contacts are separated from the insulating layer.

5. The device according to claim 4, wherein
the second parts are separated from the insulating layer.

6. The device according to claim 4, wherein
the second semiconductor layer further includes a third part located between adjacent contacts among the plurality of contacts,
the third part contacts the adjacent contacts, and
the third part has a higher carrier concentration than the first part.

7. The device according to claim 6, wherein
a portion of the third semiconductor layer is located between the second electrode and the third part.

8. The device according to claim 6, wherein
the third part contacts the insulating layer.

9. The device according to claim 6, wherein
the third part also is located between the insulating layer and the contact.

10. The device according to claim 4, wherein
the second parts are located in regions directly under every other contact in the second direction among the plurality of contacts, and are not located in regions directly under contacts other than every other contact among the plurality of contacts.

11. The device according to claim 4, further comprising:
a fourth electrode located between the first electrode and the second electrode,
the fourth electrode being connected to the third electrode,
the fourth electrode facing the first semiconductor layer via an insulating member.

12. The device according to claim 1, further comprising:
a plurality of fourth electrodes arranged in a matrix configuration along a first direction and a second direction crossing the first direction,
the plurality of fourth electrodes being connected to the third electrode,
the plurality of fourth electrodes facing the second semiconductor layer via an insulating member,
the second electrode including
a part extending in the first direction, and
a part extending in the second direction.

13. The device according to claim 12, wherein
the second electrode has a lattice shape surrounding the fourth electrodes when viewed along a third direction orthogonal to the first and second directions.

14. The device according to claim 12, wherein
the second parts contact the insulating layer.

15. The device according to claim 12, wherein
the second semiconductor layer further includes a third part located between adjacent contacts among the plurality of contacts,
the third part contacts the adjacent contacts, and
the third part has a higher carrier concentration than the second part.

16. The device according to claim 15, wherein
a portion of the third semiconductor layer is located between the second electrode and the third part.

17. The device according to claim 15, wherein
the third part contacts the insulating layer.

18. The device according to claim 15, wherein
the third part also is located between the insulating layer and the contact.

19. The device according to claim 12, wherein
the plurality of contacts includes a first contact and a second contact,
a diameter of the second contact is greater than a diameter of the first contact, and
a distance between the second contact and an intersection part of the second electrode is less than the distance between the first contact and the intersection part.
